(19) United States
(12) Patent Application Publication
(10) Pub. No.: US 2026/0150420 A1
(43) Pub. Date: May 28, 2026

(54) PHOTOELECTRIC CONVERSION DEVICE, EQUIPMENT, FORMING METHOD OF OPTICAL ELEMENT ARRAY, AND MANUFACTURING METHOD OF PHOTOELECTRIC CONVERSION DEVICE

(71) Applicant: CANON KABUSHIKI KAISHA, Tokyo (JP)

(72) Inventors: KOSUKE ASANO, Kanagawa (JP); TETSUYA KIMURA, Tokyo (JP)

(21) Appl. No.: 19/398,425

(22) Filed: Nov. 24, 2025

(30) Foreign Application Priority Data
Nov. 26, 2024 (JP) 2024-205699

(51) Int. Cl. H10F 39/00

(52) U.S. Cl. CPC H10F 39/8063; H10F 39/024; H10F 39/8053

(57) ABSTRACT

A device in which a plurality of pixels are arranged in a substrate is provided. Each of the plurality of pixels includes a portion, and an element configured to function as a light converging element and a color filter, the plurality of pixels include a first pixel and a second pixel arranged adjacent to each other, the element of the first pixel and the element of the second pixel transmit light components of different colors, respectively, and are in contact with each other, and a contact surface where the element of the first pixel and the element of the second pixel contact is tilted with respect to a normal direction of a surface of the substrate.

### BACKGROUND

### Field of the Technology

The aspect of the embodiments relates to a photoelectric conversion device, equipment, a forming method of an optical element array, and a manufacturing method of the photoelectric conversion device.

### Description of the Related Art

It is known to arrange a microlens to increase the light converging efficiency of a photoelectric conversion element, thereby improving sensitivity. Japanese Patent Laid-Open No. 2009-277732 describes a solid-state image capturing device including pixels where a microlens is arranged on a color filter corresponding to each photodiode.

In the arrangement shown in Japanese Patent Laid-Open No. 2009-277732, if the optical path length between the microlens and the color filter is large, light having entered the microlens of one pixel may enter the color filter of a pixel arranged adjacent to the pixel, and color mixture can occur. It is demanded to shorten the optical path length between a light converging element such as a microlens and a color filter.

### SUMMARY

According to an embodiment, a device in which a plurality of pixels are arranged in a substrate, wherein each of the plurality of pixels includes a portion, and an element configured to function as a light converging element and a color filter, the plurality of pixels include a first pixel and a second pixel arranged adjacent to each other, the element of the first pixel and the element of the second pixel transmit light components of different colors, respectively, and are in contact with each other, and a contact surface where the element of the first pixel and the element of the second pixel contact is tilted with respect to a normal direction of a surface of the substrate, is provided.

According to another embodiment, a method of an element array, comprising: preparing a substrate arranged with a plurality of element materials including element materials that transmit light components of different colors, respectively; forming, using an imprint process, light converging element shapes made of a cured product of a curable composition on the plurality of element materials so as to respectively correspond to the plurality of element materials; and forming a plurality of elements each functioning as a light converging element and a color filter by transferring the light converging element shapes to the plurality of element materials, respectively, by etching the cured product and the plurality of element materials, wherein the plurality of elements include a first element and a second element arranged adjacent to each other, and a contact surface where the first element and the second element contact is tilted with respect to a normal direction of a surface of the substrate, is provided.

Features of the disclosure will become apparent from the following description of embodiments with reference to the attached drawings. The following description of embodiments is described by way of example.

### BRIEF DESCRIPTION OF THE DRAWINGS

FIG. 1 is a view showing an example of the arrangement of a photoelectric conversion device according to an embodiment;

FIG. 2 is a view showing an example of the arrangement of a photoelectric conversion device of a comparative example;

FIG. 3 is a view showing an example of a manufacturing method of the photoelectric conversion device shown in FIG. 1;

FIG. 4 is a view showing the example of the manufacturing method of the photoelectric conversion device shown in FIG. 1;

FIG. 5 is a view showing the example of the manufacturing method of the photoelectric conversion device shown in FIG. 1;

FIG. 6 is a view showing the example of the manufacturing method of the photoelectric conversion device shown in FIG. 1;

FIG. 7 is a view showing the example of the manufacturing method of the photoelectric conversion device shown in FIG. 1;

FIGS. 8A to 8C are views each showing an example of the light converging elements of the photoelectric conversion device shown in FIG. 1;

FIG. 9 is a view showing a modification of the photoelectric conversion device shown in FIG. 1;

FIG. 10 is a view showing an example of a manufacturing method of the photoelectric conversion device shown in FIG. 9;

FIG. 11 is a view showing the example of the manufacturing method of the photoelectric conversion device shown in FIG. 9;

FIG. 12 is a view showing the example of the manufacturing method of the photoelectric conversion device shown in FIG. 9;

FIG. 13 is a view showing the example of the manufacturing method of the photoelectric conversion device shown in FIG. 9;

FIG. 14 is a view showing the example of the manufacturing method of the photoelectric conversion device shown in FIG. 9;

FIG. 15 is a view showing an example of the arrangement of an imprint apparatus that is used to form the light converging element of the photoelectric conversion device according to the embodiment; and

FIG. 16 is a view showing an example of the arrangement of equipment incorporating the photoelectric conversion device according to the embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

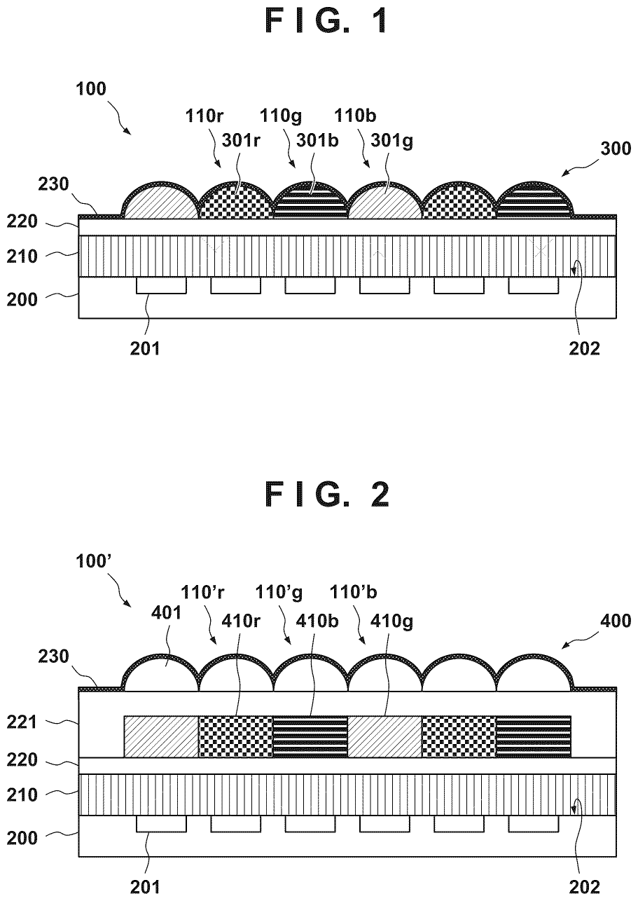

With reference to FIGS. 1 to 16, a photoelectric conversion device according to an embodiment of the disclosure will be described. FIG. 1 is a view showing an example of the arrangement of a photoelectric conversion device 100 according to this embodiment. In the photoelectric conversion device 100, a plurality of pixels 110 are arranged in a substrate 200. Each of the plurality of pixels 110 includes a photoelectric conversion portion 201 arranged in the substrate 200, and an optical element 301 arranged above the photoelectric conversion portion 201 and functioning as a light converging element and a color filter. A structure 210 is arranged between the substrate 200 and the optical element 301, and a planarizing film 220 is arranged between the structure 210 and the optical element 301.

The substrate 200 can be a semiconductor substrate using, for example, silicon or the like. The photoelectric conversion portion 201 using, for example, a photodiode or the like is provided in the substrate 200. The photoelectric conversion portion 201 converts light entering the photoelectric conversion portion into an electric signal (charge). On a surface 202 of the substrate 200, the structure 210, the planarizing film 220, the optical element 301, and the like are arranged. The surface 202 of the substrate 200 can also be called the main surface or the like.

The structure 210 can be a passivation film that protects the surface 202 of the substrate 200. For the structure 210, a so-called silicon oxide-based dielectric such as silicon oxide, silicon nitride, or silicon oxynitride may be used. For example, a conductor pattern such as a wiring pattern may be arranged in the dielectric forming the structure 210. In the surface 202 of the substrate 200, a transistor or the like connected to the wiring pattern arranged in the structure 210 can be arranged. In the arrangement shown in FIG. 1, the photoelectric conversion device 100 has a so-called front-illuminated type arrangement. However, the disclosure is not limited to this, and the photoelectric conversion device 100 may have a back-illuminated type arrangement.

The planarizing film 220 is an underlying layer for planarizing the surface on which the optical element 301 is formed. It can also be said that the optical element 301 is arranged on the planarizing film 220 serving as the underlying layer. The planarizing film 220 may be formed of an inorganic material such as silicon oxide, or may be formed of an organic material such as a resin. If the surface of the structure 210 has a desired flatness, the optical element 301 may be formed on the structure 210 serving as the underlying layer. In this case, the planarizing film 220 may be omitted (may not be arranged).

As shown in FIG. 1, an anti-reflection film 230 may be arranged to cover the optical element 301. For the anti-reflection film 230, a high refractive index material such as tantalum oxide or titanium oxide may be used. The anti-reflection film 230 may have a single-layer structure of a high refractive index material, or may have a layered structure of a high refractive index material and a low refractive index material.

In this embodiment, the optical element 301 functions as a light converging element and a color filter. In the arrangement shown in FIG. 1, the optical element 301 has a microlens shape. The optical element 301 can be a resin colored using a pigment or dye. As the resin, for example, an acrylic resin, a phenol resin, or the like can be used. As will be described later in detail, an optical element array 300 including a plurality of optical elements 301 is formed by, using an imprint process, processing a plurality of optical element materials including optical element materials that respectively transmit different colors and serve as the materials for the optical elements 301. In this embodiment, the optical elements 301 can include an optical element 301r that transmits red light, an optical element 301g that transmits green light, and an optical element 301b that transmits blue light. Here, when indicating a specific optical element among the optical elements 301, a suffix such as “r” of the optical element 301r will be added following the reference numeral, and when indicating any of the optical elements 301, it will be simply indicated as the optical element “301”. This applies to other components in a similar manner. For example, in one embodiment, the optical elements 301r, 301g, and 301b can be arranged in a Bayer array, but the disclosure is not limited to this, and the optical elements only need to be arrayed in an appropriate order. The colors of light transmitted by the optical elements 301 are not limited to red, green, and blue. The optical element array 300 may be constituted by the optical elements 301 that respectively transmit, for example, cyan, magenta, and yellow.

FIG. 2 shows a photoelectric conversion device 100′of a comparative example. In the photoelectric conversion device 100′, a microlens 401 functioning as a light converging element and a color filter 410 are separately arranged. A planarizing film 221 for suppressing the step difference in the surface of the color filter 410 is arranged between the microlens 401 and the color filter 410. Due to the planarizing film 221 or the like, the optical path length between the microlens 401 and the color filter 410 may be increased. In this case, for example, light having entered the microlens 401 arranged on a color filter 410b may enter a color filter 410r or a color filter 410g of an adjacent pixel 110′, and color mixture may occur. To the contrary, the optical element 301 according to this embodiment functions as a light converging element and a color filter, as shown in FIG. 1. By integrating the light converging element and the color filter, color mixture can be suppressed.

Next, a manufacturing method of the optical element array 300 including the plurality of optical elements 301 according to this embodiment will be described. Before describing the specific manufacturing method, an imprint process used when forming the optical element array 300 is first described. FIG. 15 schematically shows an example of the arrangement of an imprint apparatus NIL that can be used to form the optical elements 301. The imprint apparatus NIL is an apparatus that transfers the pattern of a mold M to a curable composition IM on a substrate S. As the curable composition IM, a composition (to be also referred to as a resin in an uncured state) to be cured by receiving curing energy is used. As the curing energy, an electromagnetic wave, heat, or the like is used. The electromagnetic wave is light selected from the wavelength range of 10 nm (inclusive) to 1 mm (inclusive), for example, infrared light, a visible light beam, ultraviolet light, or the like. The curable composition IM may be understood as a composition cured by light irradiation or a composition cured by heating. Among these, a photo-curable composition cured by light contains at least a polymerizable compound and a photopolymerization initiator, and may contain a nonpolymerizable compound or a solvent, as needed. The nonpolymerizable compound can be at least one material selected from the group consisting of a sensitizer, a hydrogen donor, an internal mold release agent, a surfactant, an antioxidant, and a polymer component. The curable composition IM can be applied, onto the substrate, in a film shape by a spin coater or a slit coater. The curable composition IM may be applied, onto the substrate, in a droplet shape or in an island or film shape formed by connecting a plurality of droplets using a liquid injection head. The viscosity (the viscosity at 25° C.) of the curable composition IM is, for example, 1 mPa·s (inclusive) to 100 mPa·s (inclusive).

The imprint apparatus NIL can include a substrate stage SS including a substrate chuck SC that holds the substrate S, and a substrate driving mechanism SSD that drives the substrate stage SS. The imprint apparatus NIL can also include a mold driving mechanism MD that holds and drives the mold M. The substrate driving mechanism SSD and the mold driving mechanism MD constitute a relative driving mechanism that drives at least one of the substrate S and the mold M to adjust the relative position between the substrate S and the mold M. Adjustment of the relative position by the relative driving mechanism includes driving for bringing the mold M into contact with the curable composition IM on the substrate S and driving for separating the mold M from the cured product of the curable composition IM. Adjustment of the relative position by the relative driving mechanism also includes alignment between the substrate S (a shot region thereof) and the mold M (a pattern region PR thereof). The substrate driving mechanism SSD can be configured to drive the substrate S with respect to a plurality of axes (for example, three axes including the X-axis, Y-axis, and θZ-axis, or six axes including the X-axis, Y-axis, Z-axis, θX-axis, θY-axis, and θZ-axis). The imprint apparatus NIL can include a mold deformation mechanism DM that deforms the two-dimensional shape of the pattern region PR of the mold M. The mold deformation mechanism DM can deform the pattern region PR of the mold M by, for example, applying a force to the side surface of the mold M. The mold driving mechanism MD can be configured to drive the mold M with respect to a plurality of axes (for example, three axes including the Z-axis, θX-axis, and θY-axis, or six axes including the X-axis, Y-axis, Z-axis, θX-axis, θY-axis, and θZ-axis). The imprint apparatus NIL can include a pressure controller CPC that controls the three-dimensional shape of the pattern region PR of the mold M by adjusting the pressure in a sealed space SP formed on the back surface of the mold M. It is possible to deform the pattern region PR of the mold M into a downward convex shape or planarize it by adjusting the pressure in the sealed space SP by the pressure controller CPC.

The imprint apparatus NIL can include one or a plurality of alignment scopes AS for measuring the alignment error between the shot region of the substrate S and the pattern region PR of the mold M. The imprint apparatus NIL can include a curing unit CU that forms a cured film (cured product) by curing the curable composition IM by applying curing energy to the curable composition IM via the mold M. The imprint apparatus NIL can include a dispenser DP that applies or arranges the curable composition IM onto the substrate S. The imprint apparatus NIL can include an off-axis scope OAS for detecting the position of the alignment mark of the substrate S. The imprint apparatus NIL can include a control unit CNT that controls the respective components of the imprint apparatus NIL. The control unit CNT is an information processing apparatus that can be formed from, for example, a Programmable Logic Device (PLD) such as a Field Programmable Gate Array (FPGA), an Application Specific Integrated Circuit (ASIC), a computer incorporating a program, or a combination of some or all of these.

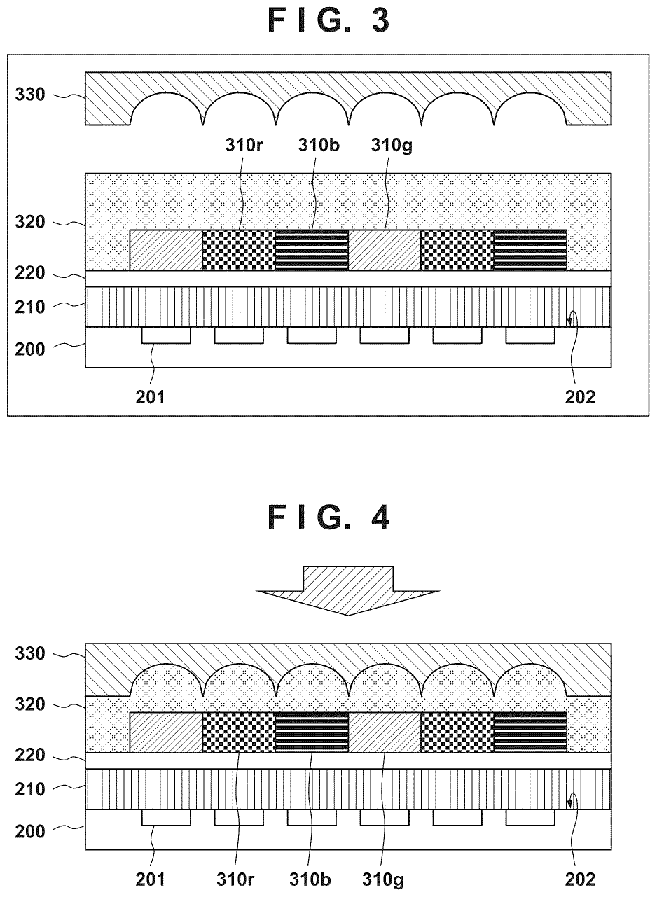

A manufacturing method of the optical element array 300 using an imprint process will be described below. First, the substrate 200 as shown in FIG. 3 is prepared, which is arranged with a plurality of optical element materials 310 including optical element materials 310r, 310g, and 310b that respectively transmit different colors. In this embodiment, as described above, the photoelectric conversion portion 201 is formed in the substrate 200. In addition, the structure 210 and the planarizing film 220 are formed on the surface 202 of the substrate 200. The plurality of optical element materials 310 are arranged on the planarizing film 220 serving as an underlying layer. However, the disclosure is not limited to this. The substrate prepared in the preparation step may be, for example, a substrate obtained by arranging the plurality of optical element materials 310 on a transparent glass or plastic substrate. The transparent substrate may not include the photoelectric conversion portion. In that case, the formed optical element array 300 can be used while being stacked with a substrate including the photoelectric conversion portions, a substrate including light emitting elements, and the like.

Then, as shown in FIG. 3, in the imprint apparatus NIL, a step of arranging a curable composition 320 (the curable composition IM in FIG. 15) by the dispenser DP so as to cover the optical element materials 310 is executed. A mold 330 (the mold M in FIG. 15) is also prepared.

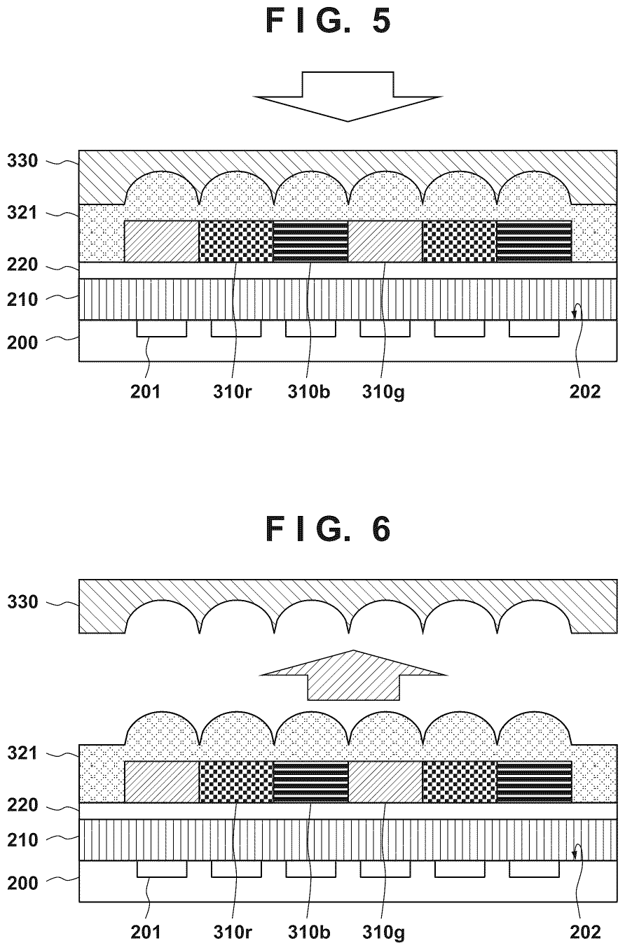

After the curable composition 320 is arranged, as shown in FIG. 4, a step of bringing the mold 330 into contact with the curable composition 320 is executed. Then, as shown in FIG. 5, in a state in which the curable composition 320 and the mold 330 are in contact with each other, a step of curing the curable composition 320 by the curing unit CU is executed. With this step, a cured product 321 of the curable composition 320 is formed. After the cured product 321 is formed, as shown in FIG. 6, a step of separating the mold 330 from the cured product 321 is executed. A process including the step of arranging the curable composition 320 on the optical element materials 310, the step of bringing the mold 330 into contact with the curable composition 320, the step of curing the curable composition 320, and the step of separating the mold 330 from the cured product 321 of the curable composition 320 can be called an imprint process. In this manner, in this embodiment, using the imprint process, light converging element shapes made of the cured product 321 of the curable composition 320 are formed on the plurality of optical element materials 310 so as to respectively correspond to the plurality of optical element materials 310.

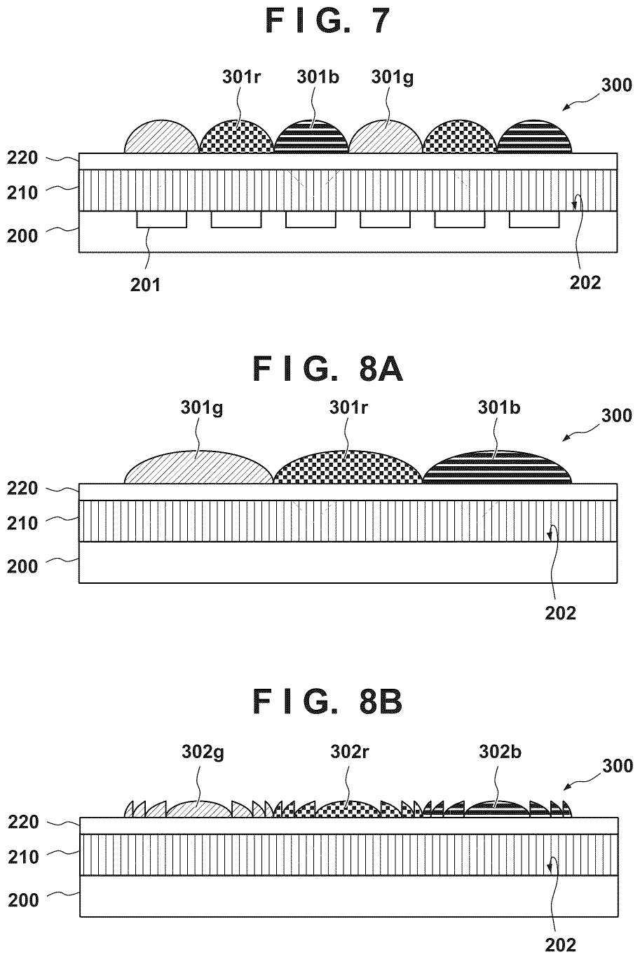

After the cured product 321 having the light converging element shapes is formed, the cured product 321 and the plurality of optical element materials 310 are etched. With this, the light converging element shapes of the cured product 321 are transferred to the plurality of optical element materials 310, respectively. Accordingly, as shown in FIG. 7, the plurality of optical elements 301 (optical element array 300) each functioning as the light converging element and the color filter are formed from the plurality of optical element materials 310. In the etching step, when the etching rate of the cured product 321 of the curable composition 320 and the etching rate of the optical element material 310 are closer in value, the light converging element shape of the cured product 321 can be more easily and accurately transferred to the optical element material 310. For example, in the etching step, the selectivity of etching rate of the optical element material 310 to the cured product 321 may be 0.7 or more and 1.3 or less. Furthermore, for example, in the etching step, the selectivity of etching rate of the optical element material 310 to the cured product 321 may be 0.9 or more and 1.1 or less. Alternatively, for example, in the etching step, the etching rate of the cured product 321 may be equal to the etching rate of the optical element material 310 (for example, the selectivity is approximately 1). For example, when the optical element material 310 (optical element 301) and the cured product 321 (curable composition 320) contain the same resin material, the selectivity of etching rate as described can be achieved. For example, the optical element material 310 (optical element 301) and the cured product 321 (curable composition 320) may contain an acrylic resin. Alternatively, for example, the optical element material 310 (optical element 301) and the cured product 321 (curable composition 320) may contain a phenol resin.

After the optical elements 301 (optical element array 300) are formed, as shown in FIG. 1, for example, the anti-reflection film 230 may be formed to cover the optical elements 301 (optical element array 300). As shown in FIG. 1, all the optical elements 301 constituting the optical element array 300 may have the same shape. Alternatively, for example, the shape of the optical element 301 may be different for each pixel 110. For example, the optical element 301r, the optical element 301b, and the optical element 301g may have different shapes in accordance with the color of light to be transmitted. For example, at least one of the optical element 301g and the optical element 301b may be formed thinner than the optical element 301r. With this, for example, sensitivity can be increased with respect to blue light to which the photoelectric conversion portion 201 using a photodiode has low sensitivity, or green light to which human eyes are sensitive. In the arrangement shown in FIG. 1, the center of the optical element 301 having the microlens shape is arranged on the center of the photoelectric conversion portion 201, but the disclosure is not limited to this. For example, the center position of the photoelectric conversion portion 201 and the center position of the optical element 301 may be shifted stepwise or continuously as they are away from the center of the substrate 200. The shape of the optical element 301 and the positional relationship with the photoelectric conversion portion 201 may be set, as appropriate, in accordance with the performance required for the optical element 301.

In this embodiment, the optical element 301 has both a function of a light converging element and a function of a color filter. Therefore, the optical path length between the light converging element and the color filter is shortened (almost eliminated), and color mixture between the pixels 110 can be suppressed. In addition, as described above, the optical element array 300 including the plurality of optical elements 301 each functioning as the light converging element and the color filter can be formed using the imprint process. This can form the optical element array 300 more easily than in a case of using a photolithography process (including an exposure step, a developing step, and the like) that uses a precise half-tone mask or the like.

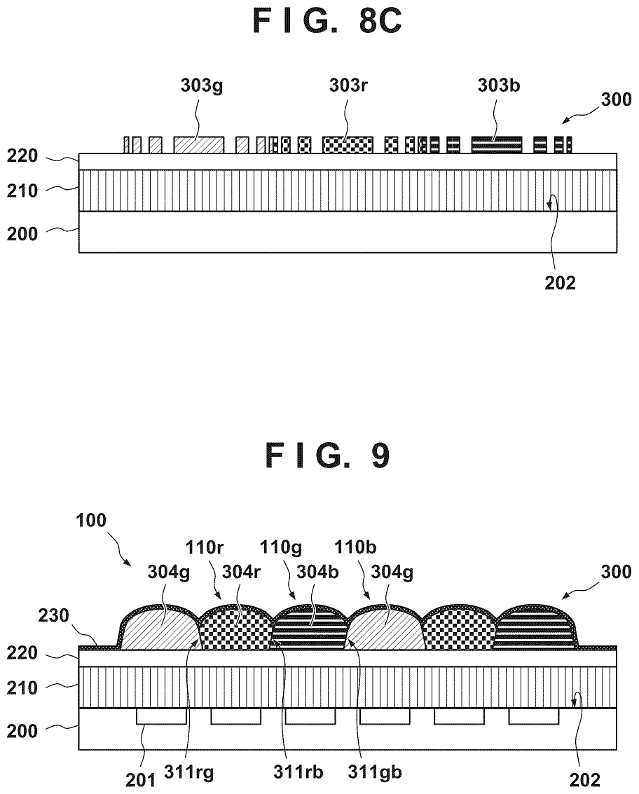

Each of FIGS. 8A to 8C shows an example of optical elements each having a light converging function. FIG. 8A shows an example where a microlens is used as the above-described optical element 301. The microlens may be a spherical lens or an aspheric lens. However, the light converging element is not limited to the microlens. As shown in FIG. 8B, a Fresnel lens may be used as an optical element 302. A Fresnel lens can have a reduced height compared to, for example, a microlens equal in power. With this, it can be facilitated to form the cured product 321 having the light converging element shape from the curable composition 320 in the imprint process. Alternatively, as shown in FIG. 8C, a binary optics may be used as the optical element 303. For example, the binary optics may be formed in a rectangular shape having a constant height in the sectional shape, as shown in FIG. 8C. With this, it can be further facilitated to form the cured product 321 having the light converging element shape from the curable composition 320 in the imprint process. However, the disclosure is not limited to this, and the binary optics may have a stepwise sectional shape.

In the arrangements shown in FIGS. 8A to 8C, the optical elements 301 to 303 are arranged such that the end portions of the optical elements contact between the adjacent pixels 110. However, the disclosure is not limited to this, and the optical elements 301 to 303 may be arranged such that, for example, the optical elements are spaced apart at a predetermined interval between the adjacent pixels 110.

Next, with reference to FIG. 9, a modification of the photoelectric conversion device 100 shown in FIG. 1 will be described. In the photoelectric conversion device 100 shown in FIG. 9. the shape of the optical element 301 arranged in the optical element array 300 is different from that in the arrangement shown in FIG. 1. The remaining arrangement may be similar to the above-described arrangement, so that differences will mainly be described, and a description of similar arrangement will be omitted, as appropriate.

In the arrangement shown in FIG. 1, the optical path length through the optical element 301 largely changes between light having entered the center of the optical element 301 and light having entered the end portion. Accordingly, for example, for the light passing through the end portion of the optical element 301b, many red and green components may also be transmitted. As a result, the quality of information (image) obtained by the photoelectric conversion device 100 can be degraded. To solve this issue, in the arrangement shown in FIG. 9, optical elements 304 of the adjacent pixels 110 are in contact with each other. With this arrangement, as compared to the optical element 301, in the optical element 304, the difference in optical path length between light having entered the center of the optical element 304 and light having entered the end portion can be reduced. This can suppress degradation of the quality of information (image) obtained by the photoelectric conversion device 100. For example, the planarizing film 220 serving as the underlying layer may not be exposed between the adjacent pixels 110. Furthermore, for example, among the plurality of pixels 110 arranged in the photoelectric conversion device 100, the planarizing film 220 serving as the underlying layer may not be exposed between the optical element 304 of one pixel 110 and the optical elements 304 of two or more pixels 110 arranged adjacent to the one pixel 110. For example, the planarizing film 220 serving as the underlying layer may not be exposed in the optical element array 300. With this arrangement, the difference in optical path length according to the light incident portions in each optical element 304 can be reduced.

For example, an optical element 304r of a pixel 110r and an optical element 304g of a pixel 110g adjacent to each other transmit light components of different colors, respectively, and are in contact with each other. Similarly, an optical element 304b of a pixel 110b and the optical element 304g of the pixel 110g adjacent to each other transmit light components of different colors, respectively, and are in contact with each other. For example, in a Bayer array, the pixel 110g including the optical element 304g that transmits green light is arranged adjacent to the pixel 110r including the optical element 304r that transmits red light and the pixel 110b including the optical element 304b that transmits blue light. In addition, in the arrangement shown in FIG. 9, a contact surface 311rg where the optical element 304g of the pixel 110g and the optical element 304 r of the pixel 110r contact is tilted with respect to the normal direction of the surface 202 of the substrate 200. Similarly, a contact surface 311gb where the optical element 304g of the pixel 110g and the optical element 304b of the pixel 110b contact is tilted with respect to the normal direction of the surface 202 of the substrate 200. Similarly, a contact surface 311rb where the optical element 304r of the pixel 110r and the optical element 304b of the pixel 110b contact is tilted with respect to the normal direction of the surface 202 of the substrate 200. In the arrangement shown in FIG. 9, the contact surface 311rg is formed such that a part of the optical element 304g of the pixel 110g is arranged between the optical element 304r of the pixel 110r and the surface 202 of the substrate 200. In addition, the contact surface 311gb is formed such that a part of the optical element 304g of the pixel 110g is arranged between the optical element 304b of the pixel 110b and the surface 202 of the substrate 200. Furthermore, the contact surface 311rb is formed such that a part of the optical element 304b of the pixel 110b is arranged between the optical element 304r of the pixel 110r and the surface 202 of the substrate 200. With reference to FIGS. 10 to 14, a manufacturing method of the optical element array 300 (photoelectric conversion device 100) including the optical elements 304 will be described below.

First, the substrate 200 as shown in FIG. 10 is prepared, which is arranged with the plurality of optical element materials 310 including the optical element materials 310r, 310g, and 310b that respectively transmit different colors. A preparation step of preparing the plurality of optical element materials 310 will be described in more detail. First, for example, a material film for the optical element material 310g is formed using a coating method or the like. Examples of the coating method include a spin coating method, a dipping method, and a spray method. Then, the material film for the optical element material 310g is patterned using a photolithography process. The material film for the optical element material 310g is exposed using an appropriate photomask. The material film for the optical element material 310g may be a negative-type photosensitive resin or a positive-type photosensitive resin. The exposed material film for the optical element material 310g is developed. If the material film for the optical element material 310g is a negative-type photosensitive resin, the exposed portion remains after the development. The portion remaining after the patterning becomes the optical element material 310g. In this case, the optical element material 310g can be formed in a tapered shape that does not have a side wall standing vertically (in the normal direction of the surface 202 of the substrate 200) from the planarizing film 220 serving as the underlying layer, but is tapered as parting from the surface 202 of the substrate 200, as shown in FIG. 10. Accordingly, the material film for the optical element material 310, which is subsequently formed by a coating method or the like, more easily enters between the formed optical element materials 310g than when the side wall of the optical element material 310g stands vertically. This can lead to improved manufacturing yield. The tapered shape of the optical element material 310g may be controlled by the defocus amount in the exposure step of the photolithography process for forming the optical element material 310g from the material film for the optical element material 310g.

Next, a material film for the optical element material 310b is formed using a coating method or the like. Examples of the coating method include a spin coating method, a dipping method, and a spray method. Then, the material film for the optical element material 310b is patterned using a photolithography process. The material film for the optical element material 310b is exposed using an appropriate photomask. The material film for the optical element material 310b may be a negative-type photosensitive resin or a positive-type photosensitive resin. The exposed material film for the optical element material 310b is developed. If the material film for the optical element material 310b is a negative-type photosensitive resin, the exposed portion remains after the development. The portion remaining after the patterning becomes the optical element material 310b. Due to the above-described shape of the optical element material 310g, the contact surface 311gb where the optical element material 310 b contacts the optical element material 310g is formed such that a part of the optical element material 310g is arranged between the optical element material 310b and the surface 202 of the substrate 200. That is, the contact surface 311gb between the optical element material 310g and the optical element material 310b is tilted with respect to the normal direction of the surface 202 of the substrate 200 where the optical element materials 310g and 310b are arranged. With this arrangement, the contact surface 311gb is formed such that a part of the optical element 304g of the pixel 110g is arranged between the optical element 304b of the pixel 110b and the surface 202 of the substrate 200, as finally shown in FIG. 9. In addition, the portion of the optical element material 310b not in contact with the optical element material 310g can be formed in a tapered shape that is tapered as parting from the surface 202 of the substrate 200 as shown in FIG. 10. Accordingly, the material film for the optical element material 310, which is subsequently formed by a coating method or the like, more easily enters between the formed optical element materials 310g and 310b than when the side walls of the optical element materials 310g and 310b stand vertically. The shape of the optical element material 310b may be controlled by the defocus amount in the exposure step of the photolithography process for forming the optical element material 310b from the material film for the optical element material 310b. As shown in FIG. 10, the end portion of the optical element material 310b may be formed to overlap on the end portion of the optical element material 310g. In other words, the film thickness of the optical element material 310b may be larger than the film thickness of the optical element material 310g.

After the optical element material 310b is formed, a material film for the optical element material 310r is formed using a coating method or the like. Examples of the coating method include a spin coating method, a dipping method, and a spray method. Then, the material film for the optical element material 310r is patterned using a photolithography process. The material film for the optical element material 310r is exposed using an appropriate photomask. The material film for the optical element material 310r may be a negative-type photosensitive resin or a positive-type photosensitive resin. The exposed material film for the optical element material 310r is developed. If the material film for the optical element material 310r is a negative-type photosensitive resin, the exposed portion remains after the development. The portion remaining after the patterning becomes the optical element material 310r. Due to the above-described shape of the optical element material 310g, the contact surface 311rg where the optical element material 310r contacts the optical element material 310g is formed such that a part of the optical element material 310g is arranged between the optical element material 310r and the surface 202 of the substrate 200. That is, the contact surface 311rg between the optical element material 310r and the optical element material 310g is tilted with respect to the normal direction of the surface 202 of the substrate 200 where the optical element materials 310r and 310g are arranged. With this arrangement, the contact surface 311 rg is formed such that a part of the optical element 304g of the pixel 110g is arranged between the optical element 304r of the pixel 110r and the surface 202 of the substrate 200, as finally shown in FIG. 9. In addition, due to the above-described shape of the optical element material 310b, the contact surface 311rb where the optical element material 310r contacts the optical element material 310b is formed such that a part of the optical element material 310b is arranged between the optical element material 310r and the surface 202 of the substrate 200. That is, the contact surface 311rb between the optical element material 310r and the optical element material 310b is tilted with respect to the normal direction of the surface 202 of the substrate 200 where the optical element materials 310r and 310g are arranged. With this arrangement, the contact surface 311rb is formed such that a part of the optical element 304b of the pixel 110b is arranged between the optical element 304r of the pixel 110r and the surface 202 of the substrate 200, as finally shown in FIG. 9. Since the shape of the optical element material 310r is formed last among the three kinds of optical element materials 310r, 310g, and 310b, it is formed in a tapered shape that is tapered as parting from the surface 202 of the substrate 200 as shown in FIG. 10. As shown in FIG. 10, the end portion of the optical element material 310r may be formed to overlap on the end portions of the optical element materials 310g and 310b. In other words, the film thickness of the optical element material 310r may be larger than the film thicknesses of the optical element materials 310g and 310b.

In this embodiment, the optical element material 310g that transmits green light is formed first, then the optical element material 310b that transmits blue light is formed, and the optical element material 310r that transmits red light is formed last. With this, the tilts of the contact surfaces 311 with respect to the normal direction of the surface 202 of the substrate 200 have the relationships as described above. However, the disclosure is not limited to this, and the optical element materials 310 that transmits the respective colors may be formed in an appropriate order. The tilt directions of the contact surfaces 311 can be decided in accordance with the order of forming the optical element materials 310. Here, the case of using the three kinds of optical element materials 310r, 310g, and 310b has been exemplarily described, but two types or four or more types of optical element materials 310 may be used. In that case as well, the tilt directions of the contact surfaces 311 can be decided in accordance with the order of forming the optical element materials 310.

In this embodiment as well, the photoelectric conversion portions 201 are formed as described above in the substrate 200 where the optical element materials 310 are arranged. The structure 210 and the planarizing film 220 are also formed on the surface 202 of the substrate 200. However, the disclosure is not limited to this, and the substrate prepared in the preparation step may be, for example, a substrate where the plurality of optical element materials 310 are arranged on a transparent glass or plastic substrate. The transparent substrate may not include the photoelectric conversion portion. In that case, the formed optical element array 300 can be used while being stacked with a substrate including the photoelectric conversion portions, a substrate including light emitting elements, and the like.

Then, an imprint process is executed in a manner similar to above. First, as shown in FIG. 10, in the imprint apparatus NIL, a step of arranging the curable composition 320 (the curable composition IM in FIG. 15) by the dispenser DP so as to cover the optical element materials 310 is executed. The mold 330 (the mold M in FIG. 15) is also prepared.

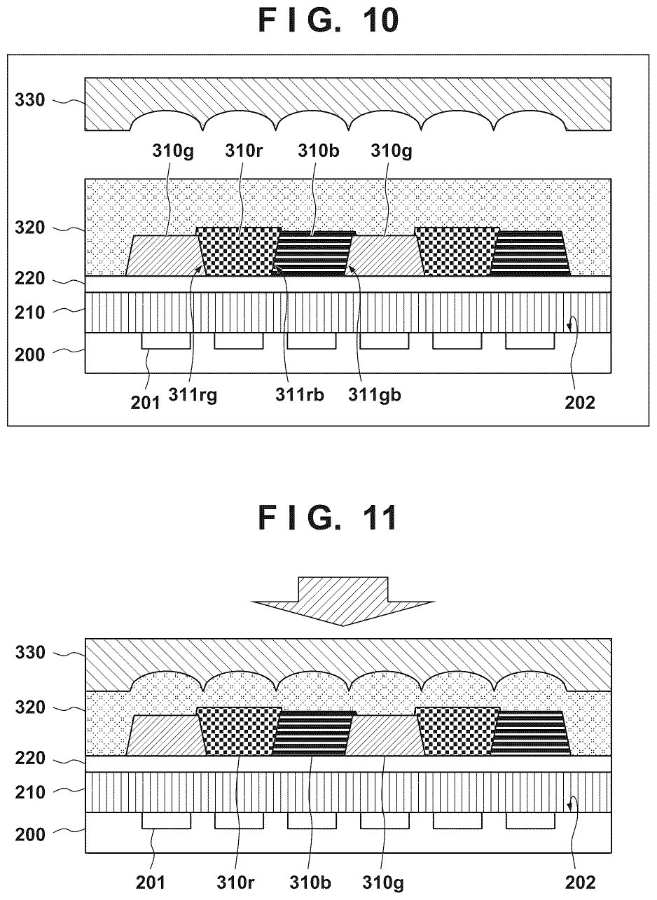

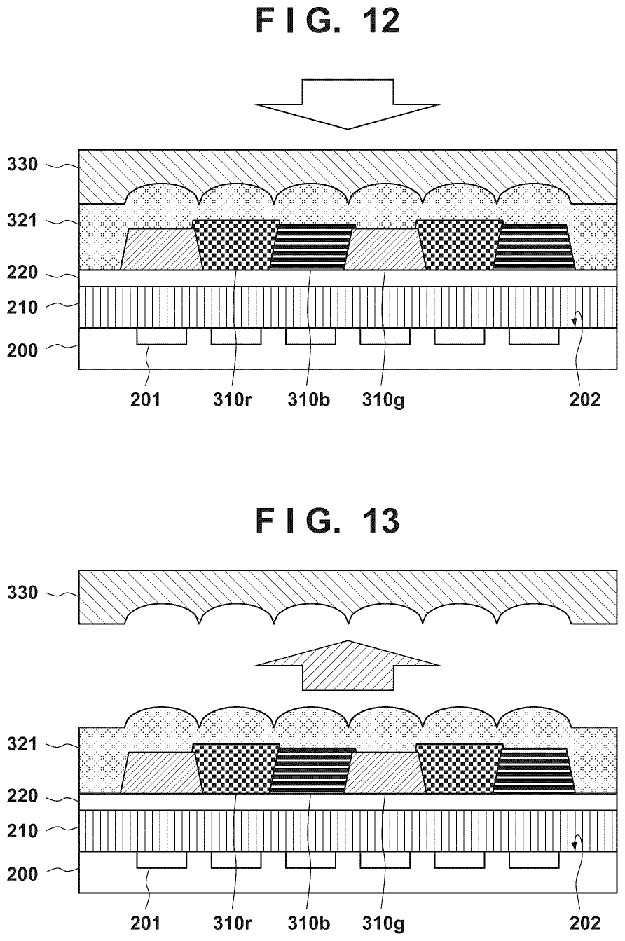

After the curable composition 320 is arranged, as shown in FIG. 11, a step of aligning the mold 330 at a predetermined position and bringing the mold 330 into contact with the curable composition 320 is executed. Then, as shown in FIG. 12, in a state in which the curable composition 320 and the mold 330 are in contact with each other, a step of curing the curable composition 320 by the curing unit CU is executed. With this step, the cured product 321 of the curable composition 320 is formed. After the cured product 321 is formed, as shown in FIG. 13, a step of separating the mold 330 from the cured product 321 is executed. In this manner, in this embodiment, using the imprint process, light converging element shapes made of the cured product 321 of the curable composition 320 are formed on the plurality of optical element materials 310 so as to respectively correspond to the plurality of optical element materials 310.

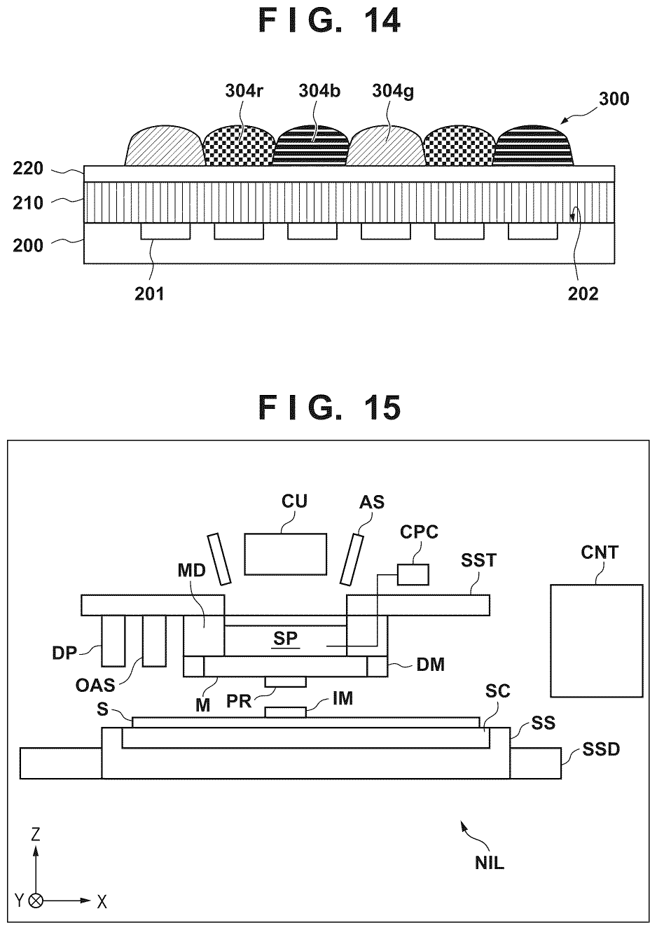

After the cured product 321 having the light converging element shapes is formed, the cured product 321 and the plurality of optical element materials 310 are etched. With this, the light converging element shapes of the cured product 321 are transferred to the plurality of optical element materials 310, respectively. Accordingly, as shown in FIG. 14, the plurality of optical elements 304 (optical element array 300) each functioning as the light converging element and the color filter are formed from the plurality of optical element materials 310. In the etching step, when the etching rate of the cured product 321 of the curable composition 320 and the etching rate of the optical element material 310 are closer in value, the light converging element shape of the cured product 321 can be more easily and accurately transferred to the optical element material 310. For example, as shown in FIGS. 10 to 13, the optical element materials 310r, 310g, and 310b may have different thicknesses. Even in such a case, by setting the etching rate of the cured product 321 of the curable composition 320 and the etching rate of the optical element material 310 to be close in value, the surface shape of the cured product 321 can be more accurately transferred to the optical element material 310.

For example, in the etching step, the selectivity of etching rate of the optical element material 310 to the cured product 321 may be 0.7 or more and 1.3 or less. Furthermore, for example, in the etching step, the selectivity of etching rate of the optical element material 310 to the cured product 321 may be 0.9 or more and 1.1 or less. Alternatively, for example, in the etching step, the etching rate of the cured product 321 may be equal to the etching rate of the optical element material 310 (for example, the selectivity is approximately 1). For example, when the optical element material 310 (optical element 304) and the cured product 321 (curable composition 320) contain the same resin material, the selectivity of etching rate as described can be achieved. For example, the optical element material 310 (optical element 304) and the cured product 321 (curable composition 320) may contain an acrylic resin. Alternatively, for example, the optical element material 310 (optical element 304) and the cured product 321 (curable composition 320) may contain a phenol resin.

After the optical elements 304 (optical element array 300) are formed, as shown in FIG. 9, for example, the anti-reflection film 230 may be formed to cover the optical elements 304 (optical element array 300). As shown in FIG. 9, all the optical elements 304 constituting the optical element array 300 may have the same shape. Alternatively, for example, the shape of the optical element 304 may be different for each pixel 110. For example, the optical element 304r, the optical element 304g, and the optical element 304b may have different shapes in accordance with the color of light to be transmitted. For example, at least one of the optical element 304g and the optical element 304b may be formed thinner than the optical element 304r. With this, for example, sensitivity can be increased with respect to blue light to which the photoelectric conversion portion 201 using a photodiode has low sensitivity, or green light to which human eyes are sensitive. In the arrangement shown in FIG. 9, the center of the optical element 304 having the microlens shape is arranged on the center of the photoelectric conversion portion 201, but the disclosure is not limited to this. For example, the center position of the photoelectric conversion portion 201 and the center position of the optical element 304 may be shifted stepwise or continuously as they are away from the center of the substrate 200. The shape of the optical element 304 and the positional relationship with the photoelectric conversion portion 201 may be set, as appropriate, in accordance with the performance required for the optical element 304.

Also in this embodiment, similar to the above-described optical element 301, the optical element 304 has both a function of a light converging element and a function of a color filter. Therefore, the optical path length between the color converging element and the color filter is shortened (almost eliminated), and color mixture between the pixels 110 can be suppressed. In addition, as described above, the optical element array 300 including the plurality of optical elements 304 each functioning as the light converging element and the color filter can be formed using the imprint process. This can form the optical element array 300 more easily than in a case of using a photolithography process (including an exposure step, a developing step, and the like) that uses a precise half-tone mask or the like.

In the arrangement shown in FIG. 9, a microlens is used as the optical element 304. However, as shown in FIGS. 8B and 8C, a Fresnel lens or a binary optics may be used as the optical element 304. In that case, the respective optical elements 304 may be arranged such that the underlying layer (the planarizing film 220 in the arrangement shown in FIG. 9) is not exposed between the optical elements 304 of the adjacent pixels 110.

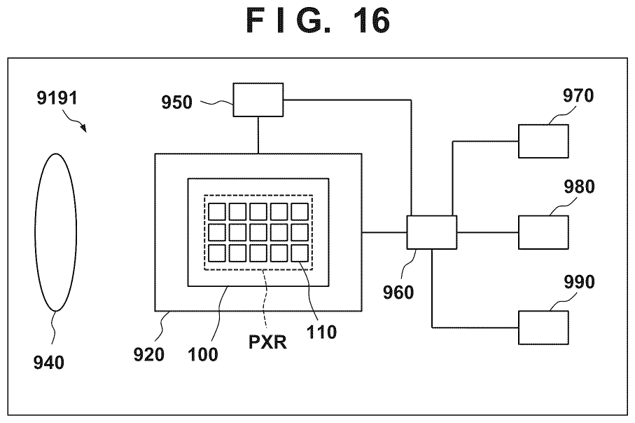

An application example of the photoelectric conversion device 100 according to this embodiment will be described here with reference to FIG. 16. FIG. 16 is a schematic view of equipment 9191 including the photoelectric conversion device 100. As shown in FIG. 16, the photoelectric conversion device 100 is housed in a package 920. The package 920 can include a base to which the photoelectric conversion device 100 is fixed and a lid member made of glass or the like which faces the photoelectric conversion device 100. In addition, the package 920 can include joining members such as bonding wires and bumps that connect the terminals provided on the base to the pads provided on the photoelectric conversion device 100.

The equipment 9191 can include at least one of an optical device 940, a control device 950, a processing device 960, a display device 970, a storage device 980, and a mechanical device 990. The optical device 940 is a component for forming an image on a pixel region PXR where the pixels 110 of the photoelectric conversion device 100 are arranged, and is implemented by, for example, a lens, a shutter, and a mirror. The control device 950 controls the photoelectric conversion device 100. The control device 950 is, for example, a semiconductor device such as an Application Specific Integrated Circuit (ASIC).

The processing device 960 processes a signal output from the photoelectric conversion device 100. The processing device 960 is a semiconductor device such as a Central Processing Unit (CPU) or an ASIC for forming an analog front end (AFE) or a digital front end (DFE). The display device 970 is an EL display device or a liquid crystal display device that displays information (image) obtained by the photoelectric conversion device 100. The storage device 980 is a magnetic device or a semiconductor device that stores the information (image) obtained by the photoelectric conversion device 100. The storage device 980 is a volatile memory such as an SRAM or a DRAM, or a nonvolatile memory such as a flash memory or a hard disk drive.

The mechanical device 990 includes a moving or propulsion unit such as a motor or an engine. In the equipment 9191, the signal output from the photoelectric conversion device 100 is displayed on the display device 970 or transmitted to an external device by a communication device (not shown) included in the equipment 9191. Hence, the equipment 9191 may further include the storage device 980 and the processing device 960 in addition to the memory circuits and arithmetic circuits included in the photoelectric conversion device 100. The mechanical device 990 may be controlled based on the signal output from the photoelectric conversion device 100.

In addition, the equipment 9191 is suitable for electronic equipment such as an information terminal (for example, a smartphone or a wearable terminal) which has a shooting function or a camera (for example, an interchangeable lens camera, a compact camera, a video camera, or a monitoring camera). The mechanical device 990 in the camera can drive the components of the optical device 940 in order to perform zooming, a focusing operation, and a shutter operation. Alternatively, the mechanical device 990 in the camera can move the photoelectric conversion device 100 in order to perform an anti-vibration operation.

Furthermore, the equipment 9191 can also be applied to an onboard camera mounted in transportation equipment such as a vehicle, a ship, an airplane, or an industrial robot. The mechanical device 990 in the transportation equipment can be used as a moving device. The equipment 9191 as the transportation equipment is suitable for a device that transports the photoelectric conversion device 100 or a device that uses an image capturing function to assist and/or automate driving (steering). The processing device 960 for assisting and/or automating driving (steering) can perform, based on the information obtained by the photoelectric conversion device 100, processing for operating the mechanical device 990 as a moving device. The equipment 9191 incorporating the photoelectric conversion device 100 can be widely applied to equipment using object recognition such as an intelligent transport system (ITS), in addition to the transportation equipment. Alternatively, the equipment 9191 may be medical equipment such as an endoscope, measurement equipment such as a distance measurement sensor, analysis equipment such as an electron microscope, or office equipment such as a copy machine.

According to the disclosure, a technique advantageous in reducing color mixture can be provided.

While the disclosure has been described with reference to embodiments, it is to be understood that the disclosure is not limited to the disclosed embodiments. The scope of the following claims is to be accorded the broadest interpretation so as to encompass all such modifications and equivalent structures and functions.

This application claims the benefit of Japanese Patent Application No. 2024-205699, filed Nov. 26, 2024, which is hereby incorporated by reference herein in its entirety.

What is claimed is:

1. A device in which a plurality of pixels are arranged in a substrate, wherein
each of the plurality of pixels includes a portion, and an element configured to function as a light converging element and a color filter,
the plurality of pixels include a first pixel and a second pixel arranged adjacent to each other,
the element of the first pixel and the element of the second pixel transmit light components of different colors, respectively, and are in contact with each other, and
a contact surface where the element of the first pixel and the element of the second pixel contact is tilted with respect to a normal direction of a surface of the substrate.

2. The device according to claim 1, wherein
the element of each of the plurality of pixels is arranged on an underlying layer, and
the underlying layer is not exposed between the element of the first pixel and the element of the second pixel.

3. The device according to claim 2, wherein
the underlying layer is not exposed between the element of the first pixel and the elements of not less than two pixels including the second pixel and arranged adjacent to the first pixel among the plurality of pixels.

4. The device according to claim 1, wherein
the plurality of pixels further include a third pixel arranged adjacent to the first pixel,
the element of the third pixel transmits a light component of a color different from the colors of the light components transmitted by the element of the first pixel and the element of the second pixel,
the element of the first pixel and the element of the third pixel are contact with each other, and
assuming that the contact surface is a first contact surface, a second contact surface where the element of the first pixel and the element of the third pixel contact is tilted with respect to the normal direction.

5. The device according to claim 4, wherein
the first contact surface is formed such that a part of the element of the first pixel is arranged between the element of the second pixel and the surface of the substrate, and
the second contact surface is formed such that a part of the element of the first pixel is arranged between the element of the third pixel and the surface of the substrate.

6. The device according to claim 1, wherein
the element of each of the plurality of pixels is a microlens.

7. The device according to claim 1, wherein
the element of each of the plurality of pixels is a Fresnel lens.

8. The device according to claim 1, wherein
the element of each of the plurality of pixels is a binary optics.

9. Equipment comprising:
the device according to claim 1; and
a processing device configured to process a signal output from the device.

10. A method of an element array, comprising:
preparing a substrate arranged with a plurality of element materials including element materials that transmit light components of different colors, respectively;
forming, using an imprint process, light converging element shapes made of a cured product of a curable composition on the plurality of element materials so as to respectively correspond to the plurality of element materials; and
forming a plurality of elements each functioning as a light converging element and a color filter by transferring the light converging element shapes to the plurality of element materials, respectively, by etching the cured product and the plurality of element materials,
wherein
the plurality of elements include a first element and a second element arranged adjacent to each other, and
a contact surface where the first element and the second element contact is tilted with respect to a normal direction of a surface of the substrate.

11. The method according to claim 10, wherein
in the forming the plurality of elements, selectivity of etching rate of the plurality of element materials to the cured product is not less than 0.7 and not more than 1.3.

12. The method according to claim 10, wherein
the plurality of element materials and the cured product contain the same resin material.

13. The method according to claim 10, wherein
each of the plurality of elements is a microlens.

14. The method according to claim 10, wherein
each of the plurality of elements is a Fresnel lens.

15. The method according to claim 10, wherein
each of the plurality of elements is a binary optics.

16. The method according to claim 10, wherein
in the preparing, the plurality of element materials include a first element material and a second element material arranged adjacent to each other,
the first element material and the second element material transmit light components of different colors, respectively, and are in contact with each other, and
a contact surface where the first element material and the second element material contact is tilted with respect to a normal direction of a surface of the substrate where the plurality of element materials are arranged.

17. The method according to claim 16, wherein
the preparing includes forming the first element material and then forming the second element material by using a photolithography process in each forming, and
a tilt of the contact surface is controlled by a defocus amount for forming the first element material.

18. A manufacturing method of a device including a plurality of portions and a plurality of color filters, wherein
the plurality of color filters are the plurality of elements formed using the method according to claim 10.
